(19) United States
(12) Patent Application Publication
(10) Pub. No.: US 2015/0380537 A1
(43) Pub. Date: Dec. 31, 2015

(54) SEMICONDUCTOR DEVICE

(71) Applicant: Takehiro KATO, (US)

(72) Inventor: Takehiro KATO, Toyota-shi (JP)

(73) Assignee: TOYOTA JIDOSHA KABUSHIKI KAISHA, Toyota-shi (JP)

(21) Appl. No.: 14/769,002

(22) PCT Filed: Feb. 22, 2013
(86) PCT No.: PCT/JP2013/054499

§ 371 Date: Aug. 19, 2015

(51) Int. Cl. H01L 29/739

(52) U.S. Cl. CPC H01L 29/7397

(57) ABSTRACT

A semiconductor device in which a first region of a first conductivity type, a second region of a second conductivity type, and a third region of the first conductivity type are laminated in this order from a front surface side of a semiconductor substrate, a trench gate electrode extending to the third region through the first region and the second region is formed, a front surface electrode is formed on the front surface, and an insulating region covering a top surface of the trench gate electrode insulates the front surface electrode and the trench gate electrode is known. The insulating region is formed to stay within a trench. The front surface electrode is formed on the front surface with no step and extends uniformly. Generation of stress concentration on the front surface electrode is suppressed, and strength and reliability of the front surface electrode may be improved.

### TECHNICAL FIELD

The present specification discloses a semiconductor device in which electrical resistance changes as voltage at a trench gate electrode changes. A semiconductor device has been known, in which a first region of a first conductivity type, a second region of a second conductivity type, and a third region of the first conductivity type are laminated in this order from a front surface side of a semiconductor substrate and in which a trench gate electrode is formed to extend through the first region and the second region to the third region. For example, a MOS (metal-oxide semiconductor) has been known, in which the first region is a source region, the second region is a body region, the third region is a drift region, and the application of voltage to the trench gate electrode causes an inversion layer to be formed in the body region so that there is electrical continuity between the source region and the drift region. Alternatively, an IGBT (insulated gate bipolar transistor) has been known, in which the first region is an emitter region, the second region is a body region, the third region is a drift region, and the application of voltage to the trench gate electrode causes an inversion layer to be formed in the body region so that there is electrical continuity between the emitter region and the drift region.

The trench gate electrode is housed in a trench in a state where the trench gate electrode is surrounded by a gate insulating film. The trench has an opening on a front surface of the semiconductor substrate. A front surface electrode is formed on the front surface of the semiconductor substrate. The front surface electrode needs to be electrically continuous with the first region, which is the source region, the emitter region, or the like, and be insulated from the trench gate electrode. In order to form the front surface electrode in a wide area extending along the front surface of the semiconductor substrate and at the same time insulate the front surface electrode and the trench gate electrode from each other, a technology for covering a top surface of the trench gate electrode with an insulating material is employed. Covering the top surface of the trench gate electrode with an insulating material allows insulation of the front surface electrode and the trench gate electrode from each other without controlling a formation area of the front surface electrode.

FIG. 5 illustrates a cross-sectional structure of a conventional IGBT disclosed in Patent Literature 1 or the like. As shown in FIG. 5, the IGBT includes a semiconductor substrate 50. The semiconductor substrate 50 includes a trench gate electrode 56 (which will be described later), and has a front surface 58. In an area where the trench gate electrode 56 is formed, an n-type emitter region 68, a p-type body region 70, an n-type drift. region 74, an n-type buffer region 76, and a p-type collector region 78 are laminated in this order from the front surface 58. A front surface electrode 62 is formed on the front surface 58 of the semiconductor substrate 50, and a back surface electrode 80 is formed on a back surface of the semiconductor substrate 50. A trench 52 is formed in the semiconductor substrate 50. The trench 52 is extending from the front surface 58 of the semiconductor substrate 50 through the emitter region 68 and the body region 70 to the drift region 74. A gate insulating film 54 covers a wall surface of the trench 52. The trench gate electrode 56, whose both side surfaces are covered with the gate insulating film 54, is filled in the trench 52. The body contact region 69 is formed instead of the emitter region 68 in an area away from the trench gate electrode 56. An insulating film 60 covers a top surface of the trench gate electrode 56. The insulating film 60 stays not only in the trench 52, but also extends onto the front surface 58 of the semiconductor substrate 50. The front surface electrode 62 is formed in a wide area on the front surface 58 of the semiconductor substrate 50. The front surface electrode 62 needs to be electrically continuous with the emitter region 68 and the body contact region 69 and be insulated from the trench gate electrode 56. The insulating film 60 covers a top portion of the trench gate electrode 56, but does not completely cover the emitter region 68.

In the conventional semiconductor device, the front surface electrode 62 is formed on a stepped surface. That is, the front surface electrode 62 is formed on a surface where there is a mixture of an area A where the front surface 58 of the semiconductor substrate 50 is exposed without being covered with the insulating film 60 and an area B where the front surface 58 of the semiconductor substrate 50 is covered with the insulating film 60. Since the insulating film 60 formed on the front surface 58 of the semiconductor substrate 50 has a thickness C, the front surface electrode 62 has a back surface that is not flat but is an uneven surface. Since the back surface is uneven, the front surface electrode 62 has projections and depressions formed on and in its front surface.

FIG. 5 illustrates a case where the first region of the first conductivity type is the n-type emitter region 68, the second region of the second conductivity type is the p-type body region 70, and the third region of the first conductivity type is the n-type drift region 74. The application of voltage to the trench gate electrode 56 causes a portion of the body region 70 that faces the trench gate electrode 56 across the gate insulating film 54 to be inverted to an n-type so that there is electrical continuity between the emitter region 68 and the drift region 74. An n-type layer 72 is inserted at an intermediate depth of the body region 70, and the body region 70 is separated by the n-type layer 72 into an upper body region 70a and a lower body region 70b. The second region of the second conductivity type may be divided into a plurality of regions. Alternatively, the first region of the first conductivity type may be a source region, and a drain region may be laminated in place of the buffer region 76 and the collector region 78.

### CITATION LIST

### Patent Literature

### Patent Literature 1

Japanese Patent Application Publication No. 2009-295778 A

### SUMMARY OF INVENTION

### Technical Problem

The semiconductor device is used with the front surface electrode 62 bonded to a metal plate 66 by a solder layer 64. The adhesion between the front surface electrode 62 and the solder layer 64 is improved by a soldering electrode 63. Since the semiconductor device generates heat during operation and is cooled after operation, the semiconductor device is subjected to a heat cycle. The metal plate 66, the solder layer 64, the soldering electrode 63, the front surface electrode 62, and the semiconductor substrate 50 differ in coefficient of thermal expansion from one another. When the semiconductor device is subjected to a heat cycle, stress acts on the front surface electrode 62.

Since the conventional front surface electrode 62 is formed on a surface with projections and depressions, it is not uniformly spread, and has projections and depressions on both of its front and back surfaces. Therefore, stress concentration occurs on some positions of the front surface electrode 62. The conventional front surface electrode 62 is easily damaged at the positions of stress concentration when the semiconductor device is subjected to a heat cycle. Therefore, the conventional front surface electrode 62 is low in reliability

For improvement in performance of the semiconductor device, the distance between trenches 52 tends to become shorter. Further, the environment in which the front surface electrode 62 is formed tends to become lower in temperature. When the distance between trenches 52 becomes shorter, increased stress acts on the front surface electrode 62, and when the environment in which the front surface electrode 62 is formed becomes lower in temperature, the front surface electrode 62 becomes easily damageable by stress. A technology that reduces generation of stress concentration positions on a front surface electrode is needed.

The present specification discloses a technology for achieving a front surface electrode with less occurrence of stress concentration, less damage, and higher reliability.

### Solution to Problem

A semiconductor device disclosed herein includes: a semiconductor substrate; and a front surface electrode formed on a front surface of the semiconductor substrate.

In at least in a part of the semiconductor substrate, a laminated structure is formed in which a first region of a first conductivity type, a second region of a second conductivity type, and a third region of the first conductivity type are laminated in this order from a front surface side of the semiconductor substrate. A trench is formed to extend from the front surface of the semiconductor substrate through the first region and the second region to the third region. A trench gate electrode is formed in the trench. An insulating region is formed on a top surface of the trench gate electrode. The insulating region insulates the front surface electrode and the trench gate electrode from each other. In a case of the semiconductor device described herein, the insulating region is housed within the trench, That is, the insulating region does not extend to an upper place than the front surface of the semiconductor substrate. In a side view of the semiconductor substrate, a top end of the insulating region stays at a position that is equal to or deeper than the front surface of the semiconductor substrate.

A MOS may be obtained when the first region is a source region, the second region is a body region, and the third region is a drift region. An IGBT may be obtained when the first region is an emitter region, the second region is a body region, and the third region is a drift region.

In the case of the semiconductor device described above, the front surface of the semiconductor substrate before the front surface electrode is formed is substantially flat. The front surface electrode is formed on the substantially flat front surface of the semiconductor substrate to be a layer that extends homogenously and uniformly along the front surface of the semiconductor substrate. Stress concentration on the front surface electrode is less likely to occur. Even when the semiconductor device is subjected to a heat cycle, it is possible to prevent strong stress from acting on a particular position on the front surface electrode. This improves reliability of the front surface electrode.

When a bottom surface of the insulating region (i.e. the top surface of the trench gate electrode) is shallower than a bottom surface of the first region, the application of voltage to the trench gate electrode may cause an inversion layer to be formed in the second region which divides the first region and the third region from each other. The trench gate electrode does not need to extend up to the front surface of the semiconductor substrate. Since the trench gate electrode may stay at a deeper level than the front surface of the semiconductor substrate, the insulating region covering the top surface of the trench gate electrode can be kept housed within the trench.

A fourth region of the first conductivity type may be formed at an intermediate depth of the second region, and the second region may be separated by the fourth region into an upper second region and a lower second region.

The trench does not need to be constant in width. For example, the trench may be formed by a deep trench that is small in width and a shallow trench that is large in width. In that case, a configuration can be adopted in which the deep trench is filled with the trench gate electrode and the shallow trench is filled with an insulating material.

### BRIEF DESCRIPTION OF DRAWINGS

FIG. 1 is a cross-sectional view of a semiconductor device of a first embodiment.

FIG. 2 is a diagram showing a process of manufacturing the semiconductor device of the first embodiment.

FIG. 3 is a cross-sectional view of a semiconductor device of a second embodiment.

FIG. 4 is a diagram showing a process of manufacturing the semiconductor device of the second embodiment.

FIG. 5 is a cross-sectional view of a conventional semiconductor device.

### DESCRIPTION OF EMBODIMENTS

### First Embodiment

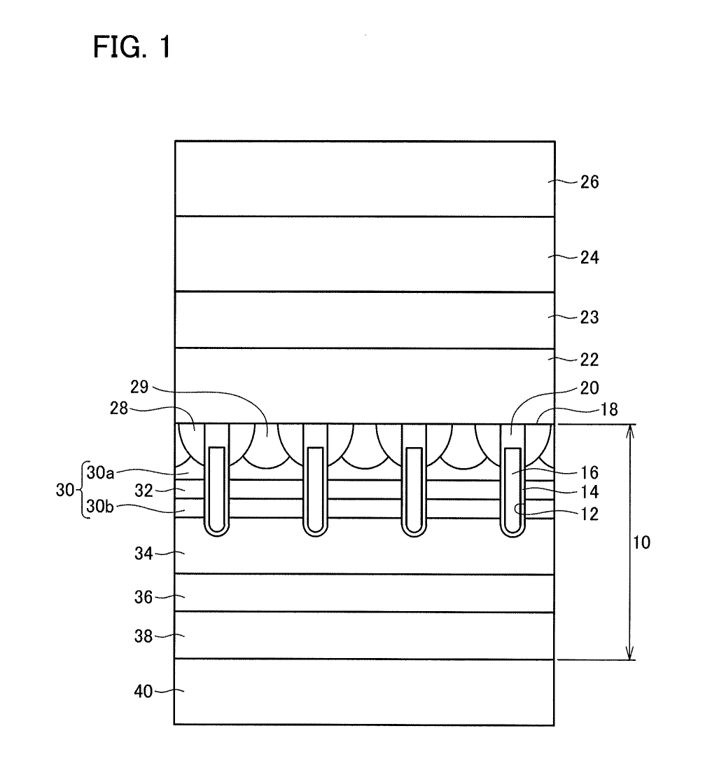

FIG. 1 is a cross-sectional view of a semiconductor device of a first embodiment. The semiconductor device comprises a semiconductor substrate 10, a front surface electrode 22, a soldering electrode 23, and a back surface electrode 40. The front surface electrode 22 is an emitter electrode, and is bonded to a metal plate 26 via the soldering electrode 23 and a solder layer 24 and used in this configuration. The back surface electrode 40 is a collector electrode, and is bonded to a conductor side (not shown) by a solder layer (not shown) and used in this configuration. The semiconductor device is a vertical IGBT in which a change in resistance between the front surface electrode 22 and the back surface electrode 40 occurs in response to a change in voltage at trench gate electrodes 16. The front surface electrode 22 is uniformly and homogenously spread along a front surface of the semiconductor substrate 10, and the back surface electrode 40 is uniformly and homogenously spread along a back surface of the semiconductor substrate 10.

In each area where the trench gate electrode 16 is formed, a first region of a first conductivity type (which in the present embodiment is an n-type emitter region 28), a second region of a second conductivity type (which in the present embodiment is a p-type body region 30), and a third region of the first conductivity type (which in the present embodiment is an n-type drift region 34), an n-type buffer region 36, and a p-type collector region 38 are laminated in this order from a front surface 18 side of the semiconductor substrate 10. The emitter region 28 is formed in some areas of the front surface 18 of the semiconductor substrate 10, and in the remaining areas, a body contact region 29 is formed. A fourth region 32 of the first conductivity type (which in the present embodiment an n-type layer) reduces an on-voltage by activating a conductivity modulation phenomenon that occurs in the drift region 34 when the IGBT is on. The body region 30 is separated by the n-type layer 32 into an upper body region 30a and a lower body region 30b. The second region of the second conductivity type may be divided into a plurality of regions. The n-type layer 32 may be omitted.

In the area where a laminated structure of the emitter region 28, the body region 30, and the drift region 34 is formed, a trench 12 is formed to extend from the front surface 18 of the semiconductor substrate 10 through the emitter region 28 and the body region 30 to the drift region 34. A wall surface of the trench 12 is covered with a gate insulating film 14. Each trench gate electrode 16 is housed in the corresponding trench 12. Both side surfaces of the trench gate electrode 16 are covered with the gate insulating film 14.

A top surface of each trench gate electrode 16 stays at a deeper level than the front surface 18 of the semiconductor substrate 10, but is at a higher level than a bottom surface of the emitter region 28. The body layer 30, which separates the emitter region 28 and the drift region 34 from each other, faces the trench gate electrode 16 across the gate insulating film 14 over an entire thickness of the body layer 30. The application of voltage to the trench gate electrode 16 causes an inversion layer to be formed in a portion of the body region 30 that faces the trench gate electrode 16 across the gate insulating film 14. Since the inversion layer is continuously formed through the entire thickness of the body region 30 separating the emitter region 28 and the drift region 34 from each other, the application of voltage to the trench gate electrode 16 generates electrical continuity between the emitter region 28 and the drift region 34.

The top surface of each trench gate electrode 16 is covered with an insulating region 20 formed by an insulating material. The insulating region 20 is housed in the trench 12, and does not protrude upward from the front surface 18 of the semiconductor substrate 10. Since, as mentioned above, the top surface of the trench gate electrode 16 stays at a deeper level than the front surface 18 of the semiconductor substrate 10, the insulating region 20 covering the top surface of the trench gate electrode 16 can be held within the trench 12.

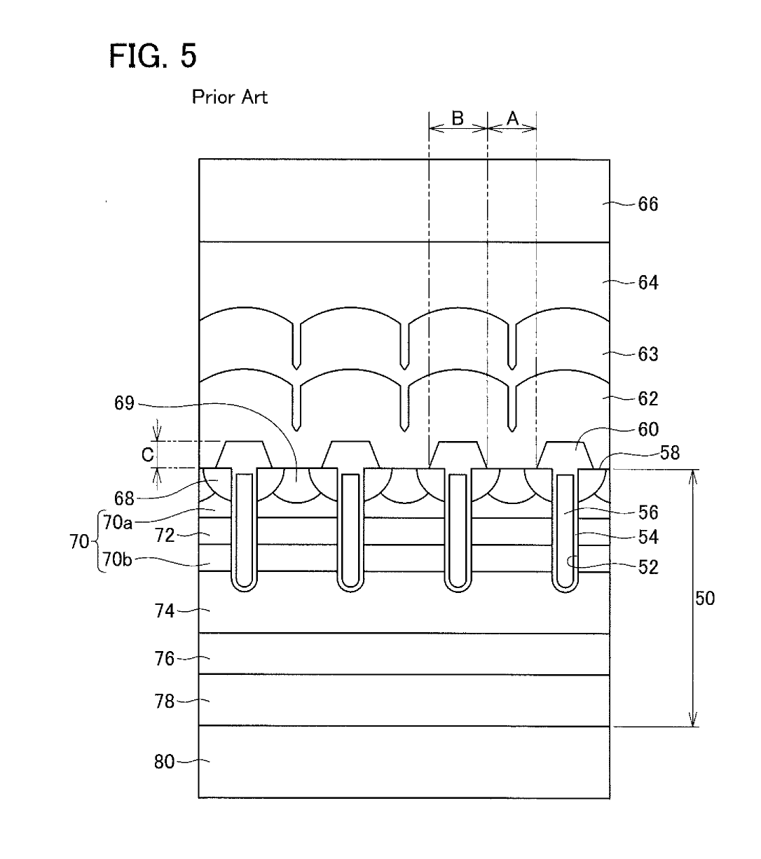

It is preferable that a top surface of the insulating region 20 substantially matches the front surface 18 of the semiconductor substrate 10. However, the top surface of the insulating region 20 may be at a deeper level than the front surface 18 of the semiconductor substrate 10. As will be mentioned later, it is possible to keep the difference in level between the top surface of the insulating region 20 and the front surface 18 of the semiconductor substrate 10 smaller than the thickness C (see FIG. 5) of the insulating film 60, and thus even in the latter case, the front surface electrode 22 can be formed on a substantially flat surface. The method of manufacturing described below makes it possible to keep the difference in level between the top surface of the insulating region 20 and the front surface 18 of the semiconductor substrate 10 equal to or smaller than 0.1 μm. For this reason, the front surface electrode 22 extends uniformly with a uniform thickness along the front surface 18 of the semiconductor substrate 10. This makes a phenomenon to occur in reduced frequency, in which stress acting on the front surface electrode 22 is concentrated on particular positions on the front surface electrode 22. That is, a phenomenon in which the stress is concentrated on the particular positions on the front surface electrode 22 and the front surface electrode 22 is damaged in the positions of stress concentration is less likely to occur. Since the front surface electrode 22 extends uniformly with a uniform thickness, the front surface electrode 22 is high in reliability. The same applies to the soldering electrode 23 formed on the front surface of the front surface electrode 22. Since the soldering electrode 23 extends uniformly with a uniform thickness, the soldering electrode 23 is high in reliability.

When the positions of stress concentration are less likely to be generated on the front surface electrode 22, there is a wider choice of materials for use as a material of which the front surface electrode 22 is to be made and there are wider choices of methods and conditions for the formation of the front surface electrode 22. This enables the front surface electrode 22 to be formed in a low-temperature environment, and the front surface electrode thus formed may be provided with fine in crystal grain size and high in mechanical strength (Hall-Petch law). Further, the front surface electrode 22 can be formed with a choice of such a condition that warpage hardly occurs in the semiconductor substrate.

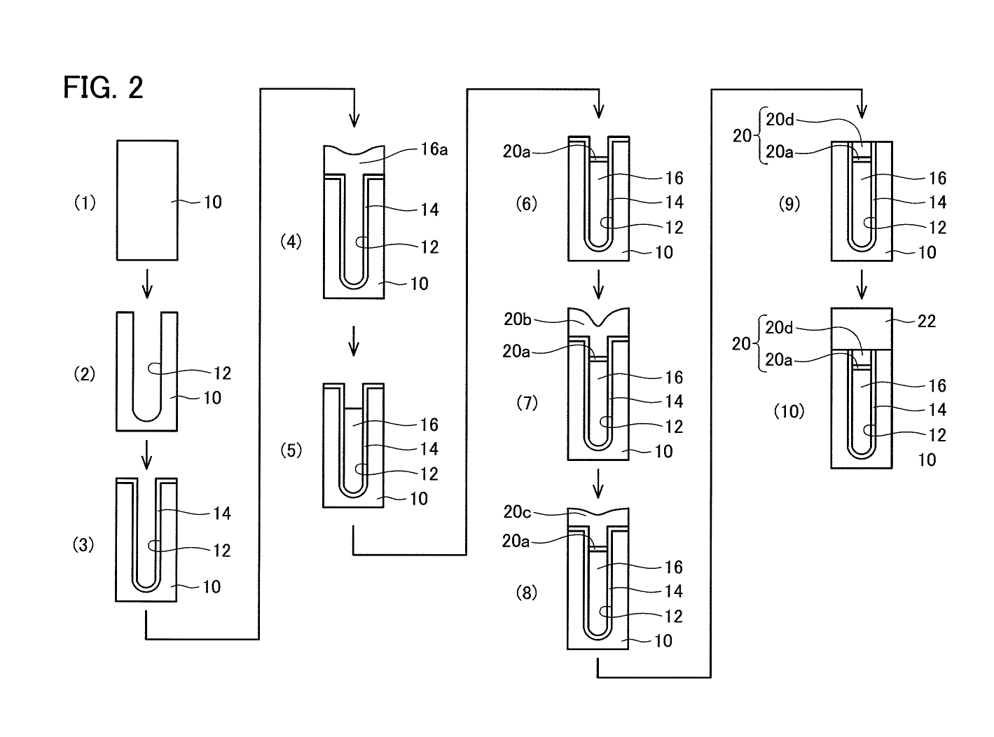

FIG. 2 shows a process of manufacturing the semiconductor device of the first embodiment. In FIG. 2, only parts associated with the trench 12 are described. The method for the manufacturing of the emitter region 28 and the like is the same as the conventional method, and as such, is not described below.

(1) of FIG. 2 shows a stage at which the semiconductor substrate 10 has been prepared.
(2) of FIG. 2 shows a stage at which the trench 12 has been formed by anisotropic etching. Anisotropic dry etching or anisotropic wet etching is available.
(3) of FIG. 2 shows a stage at which an oxide film has been formed on side surfaces and the like of the trench 12 by heat treatment. The oxide film thus formed on the side surfaces of the trench 12 and the like serves as the gate insulating film 14.
(4) of FIG. 2 shows a stage at which the trench 12 both side surfaces of which were covered with the gate insulating film 14 has been filled with polysilicon 16a by CVD or PVD. The CVD or the PVD is performed while the polysilicon 16a is being doped with an impurity. Alternatively, the polysilicon 16a may be doped with an impurity after the filling. At this stage, the polysilicon 16a is deposited until it covers the front surface 18 of the semiconductor substrate 10.
(5) of FIG. 2 shows a stage at which the polysilicon 16a has been etched, starting at its front surface. At this stage, the etching is performed until a top surface of the polysilicon 16 becomes deeper than the front surface 18 of the semiconductor substrate 10 and shallower than the bottom surface of the emitter region 28. Specifically, the etching is performed until such a distance is secured between the top surface of the polysilicon 16 and the front surface 18 of the semiconductor substrate 10 that the insulating region 20 is formed with a sufficient thickness to insulate the trench gate electrode 16 and the front surface electrode 22 from each other. A portion of the polysilicon that remains in the trench 12 serves as the trench gate electrode 16.
(6) of FIG. 2 shows a stage at which an oxide film 20a has been formed on the top surface of the trench gate electrode 16 by heat treatment. As will be mentioned later, the oxide film 20a serves as a part of the insulating region 20. When treated with heat, the oxide film 20a expands downward along the boundary between the gate insulating film 14 and the trench gate electrode 16. At the stage shown in (5) of FIG. 2, the etching is ended when a bird's beak of the oxide film 20a extending downward is at such a depth as not to reach the bottom surface of the emitter region 28. At the stage shown in (6) of FIG. 2, the front surface 18 of the semiconductor substrate 10 is covered with the oxide film.
(7) of FIG. 2 shows a stage at which silicon oxide 20b has been deposited by CVD or PVD. The silicon oxide 20b is integrated with the oxide film 20a formed on the top surface of the gate trench electrode 16, covers the top surface of the gate trench electrode 16, fills the trench 12, and is further deposited on the front surface 18 of the semiconductor substrate 10. In the place where the trench 12 is present, a depressed portion is formed in a front surface of the silicon oxide 20b due to the influence of the top surface of the trench gate electrode 16 being lower than the front surface 18 of the semiconductor substrate 10.
(8) of FIG. 2 shows a stage at which the front surface of the silicon oxide 20b has been smoothed by heat treatment. The depressed portion is smoothed, but does not disappear.
(9) of FIG. 2 shows the stage at which silicon oxide 20c having a smoothed front surface has been etched, starting at its front surface. At this stage, the etching is performed until a front surface of silicon oxide 20 formed in the trench 12 substantially matches or is slightly lower than the front surface 18 of the semiconductor substrate 10. In this etching, not only the silicon oxide deposited at the stages shown in (7) and (8) of FIG. 2 but also the oxide film formed on the front surface 18 of the semiconductor substrate 10 at the stages shown in (3) and (6) of FIG. 2 are etched. When the oxide film formed on the front surface 18 of the semiconductor substrate 10 is etched, the emitter region 28 and the body contact region 29, which have been present under the oxide film, are exposed. With the continuing dry etching of the silicon oxide, a change takes place in composition of exhaust gas at a time when the emitter region 28 and the body contact region 29 have been exposed. Measurement of the composition of the exhaust gas allows determination of the point in time at which the emitter region 28 and the body contact region 29 have been exposed as a result of the etching of the oxide films, which had been deposited at the stages shown in (7) and (8) of FIG. 2 and formed at the stages shown in (3) and (6) of FIG. 2. Once the etching has been continued up to this point in time, the front surface of the silicon oxide 20d formed in the trench 12 will not protrude from the front surface 18 of the semiconductor substrate 10. This allows the front surface of the silicon oxide 20d to match or be lower than the front surface 18 of the semiconductor substrate 10. Further, when the etching is finished at the point in time at which the emitter region 28 and the body contact region 29 have been exposed, the front surface of the silicon oxide 20d remaining in the trench 12 will not be much lower than the front surface 18 of the semiconductor substrate 10. This allows the front surface of the silicon oxide 20d remaining in the trench 12 to substantially match the front surface 18 of the semiconductor substrate 10 or be slightly lower than the front surface 18 of the semiconductor substrate 10. At this stage, the front surface of the silicon oxide 20d remaining in the trench 12 and the oxide film 20a formed on the top surface of the trench gate electrode 16 are integrated with each other to form the insulating region 20 to insulate the trench gate electrode 16 and the front surface electrode 22 from each other. The insulating region 20 stays in the trench 12, and will not protrude onto the front surface 18 of the semiconductor substrate 10.
(10) of FIG. 2 shows a stage at which the front surface electrode 22 has been formed in the area over the front surface 18 of the semiconductor substrate 10 and the front surface of the insulating region 20. Since a front surface on which the front surface electrode 22 has been formed is flat, the front surface electrode 22 thus obtained extends uniformly with a uniform thickness.

### Second Embodiment

A second embodiment is described. In the following, only points of differences between the second embodiment and the first embodiment are described, and repetition of the description of the first embodiment is omitted. Components of the second embodiment that are similar to those of the first embodiment are given the same reference numerals.

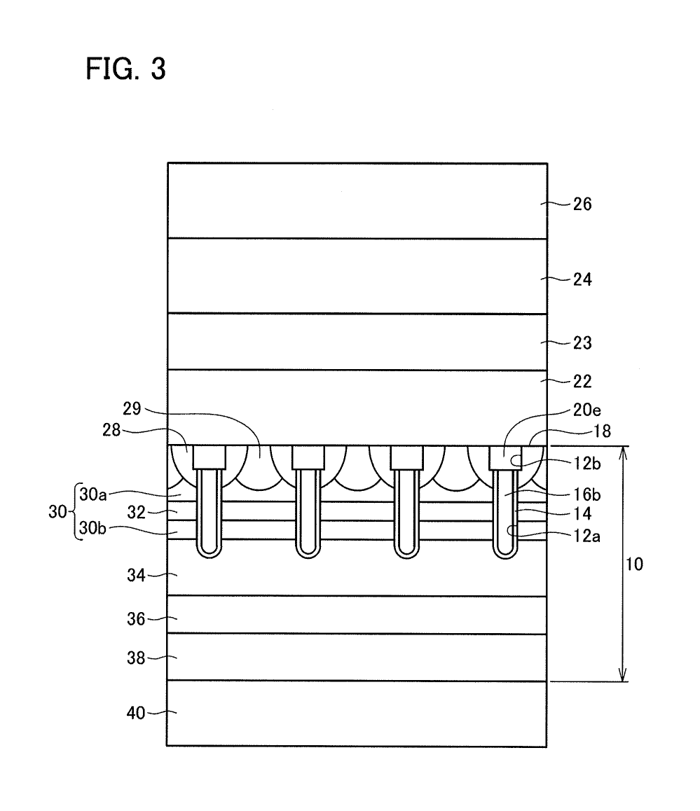

In the second embodiment, as shown in FIG. 3, each trench 12 is formed by a deep trench 12a and a shallow trench 12b. The deep trench 12a is small in width, and the shallow trench 12b is large in width. The deep trench 12a is filled with a trench gate electrode 16. The trench gate electrode does not extend into the shallow trench 12b, and the shallow trench 12b is filled with an insulating material. Housed in the shallow trench 12b is an insulating region 20e covering a top surface of the trench gate electrode.

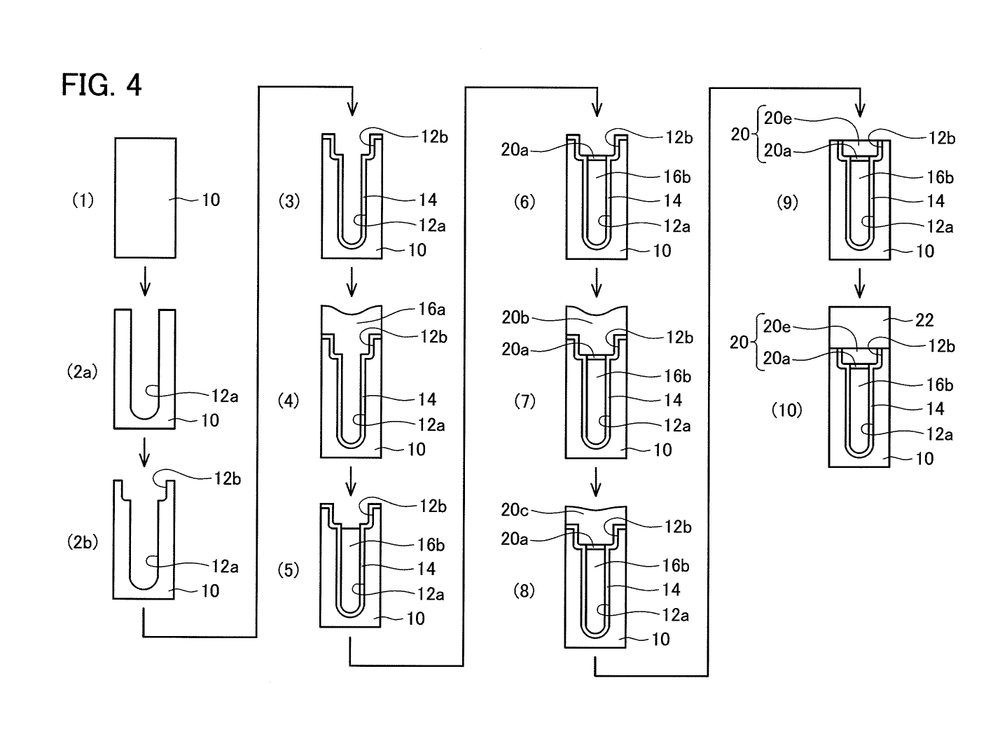

FIG. 4 shows a process of manufacturing. At a stage (2a), a trench is formed which is equal in width to the deep trench 12a and which extends from the front surface of the semiconductor substrate 10 to the drift region. At a stage (2b), the shallow trench 12b is formed. At a stage (5), the polysilicon 16a is etched until a bottom of the shallow trench 12b is exposed. At a stage (9), the insulating material filling the shallow trench 12b is left. The insulating region 20e covering the top surface of the trench gate electrode is formed by the insulating material filling the shallow trench 12b and the oxide film 20a. The other stages are the same as those of the first embodiment.

While embodiments of the present invention have been described above in detail, these embodiments are merely illustrative and place no limitation on the scope of the patent claims. The technology described in the patent claims also encompasses various changes and modifications to the specific examples described above.

The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

### REFERENCE SIGNS LIST

10: Semiconductor substrate

12: Trench

12a: Deep trench

12b: Shallow trench

14: Gate insulator film

16: Trench gate electrode

18: Front surface of the semiconductor substrate

20: Insulating region

20a: Cap film on a top surface of the trench gate electrode

20e: Insulating region filling the shallow trench

22: Emitter electrode (front surface electrode)

23: Soldering electrode

24: Solder layer

26: Metal plate

28: Emitter region (first region of a first conductivity type)

29: Body contact region

30: Body region (second region of a second conductivity type)

30a: Upper body region

30b: Lower body region

32: n-type layer (fourth region of the first conductivity type)

34: Drift layer (third region of the first conductivity type)

36: Buffer region

38: Collector region

40: Collector electrode (back surface electrode)

1-6. (canceled)

7. A semiconductor device comprising:
a semiconductor substrate; and
a front surface electrode formed on a front surface of the semiconductor substrate,
wherein
in at least a part of the semiconductor substrate, a laminated structure is formed in which a first region of a first conductivity type, a second region of a second conductivity type, and a third region of the first conductivity type are laminated in this order from a front surface side of the semiconductor substrate,
a trench is formed to extend from the front surface of the semiconductor substrate through the first region and the second region to the third region,
the trench comprises a deep trench that is small in width and a shallow trench that is large in width,
the deep trench is filled with the trench gate electrode,
the shallow trench is filled with an insulating material forming an insulating region which covers a top surface of the trench gate electrode to insulate the front surface electrode and the trench gate electrode from each other, and
the insulating region is housed within the trench.

8. The semiconductor device as set forth in claim 7, wherein
a bottom surface of the insulating region is shallower than a bottom surface of the first region.

9. The semiconductor device as set forth in claim 8, wherein
the first region is a source region, the second region is a body region, and the third region is a drift region.

10. The semiconductor device as set forth in claim 9, wherein
a fourth region of the first conductivity type is formed at an intermediate depth of the second region, and
the second region is separated by the fourth region into an upper second region and a lower second region.

11. The semiconductor device as set forth in claim 8, wherein
the first region is an emitter region, the second region is a body region, and the third region is a drift region.

12. The semiconductor device as set forth in claim 11, wherein
a fourth region of the first conductivity type is formed at an intermediate depth of the second region, and
the second region is separated by the fourth region into an upper second region and a lower second region.

13. The semiconductor device as set forth in claim 7, wherein
a fourth region of the first conductivity type is formed at an intermediate depth of the second region, and
the second region is separated by the fourth region into an upper second region and a lower second region.
